(19) United States
(12) Patent Application Publication
(10) Pub. No.: US 2014/0117379 A1
(43) Pub. Date: May 1, 2014

(54) SEMICONDUCTOR DEVICE AND METHOD OF MANUFACTURING THE SAME

(71) Applicant: HYUNDAI MOTOR COMPANY, Seoul (KR)

(72) Inventors: Youngkyun JUNG, Seoul (KR); Kyoung-Kook Hong, Hwaseong-si (KR); Jong Seok Lee, Suwon-si (KR); Dae Hwan Chun, Gwangmyung-si (KR)

(73) Assignee: Hyundai Motor Company, Seoul (KR)

(21) Appl. No.: 13/729,641

(22) Filed: Dec. 28, 2012

(30) Foreign Application Priority Data
Nov. 1, 2012 (KR) 10-2012-0123011

(51) Int. Cl. H01L 29/16; H01L 21/36

(52) U.S. Cl. CPC H01L 29/1608; H01L 21/36
USPC 257/77; 438/478

(57) ABSTRACT

A method of manufacturing a semiconductor device includes sequentially forming an n− type epitaxial layer, a p type epitaxial layer, and a first n+ region on a first surface of an n+ type silicon carbide substrate, and forming a trench through the first n+ region and the p type epitaxial layer, wherein the forming of the trench includes forming a photosensitive layer pattern on the first n+ region, etching the first n+ region and the p type epitaxial layer by using the photosensitive layer pattern as a mask, forming a buffer layer by using amorphous carbon on the first n+ region after the photosensitive layer pattern is removed, forming a buffer layer pattern by etching the buffer layer, etching using the buffer layer pattern as the mask, isotropically etching to form a second portion of the trench, and removing the buffer layer pattern.

### CROSS-REFERENCE TO RELATED APPLICATION

The present application claims priority of Korean Patent Application Number 10-2012-0123011 filed Nov. 1, 2012, the entire contents of which application is incorporated herein for all purposes by this reference.

### BACKGROUND OF INVENTION

1. Field of Invention

The present invention relates to a semiconductor device including silicon carbide (SiC), and a method of manufacturing the same.

2. Description of Related Art

In accordance with the recent trend of enlarging size and capacity of application equipment, a demand for a semiconductor device for electric power, having a high breakdown voltage, a high current, and a high-speed switching characteristic has been raised.

Accordingly, many studies and developments of a MOSFET (metal oxide semiconductor field transistor) using silicon carbide (SiC) have been made instead of a known MOSFET using silicon. Particularly, many developments of a vertical type trench MOSFET have been made.

The MOSFET is the most general electric field effect transistor in a digital circuit and an analog circuit among semiconductor devices for electric power.

In the case of the vertical type trench MOSFET, an etching technology of forming a trench in a form suitable to a semiconductor substrate is required. Since silicon carbide has hardness and oxidation resistance that are higher than those of silicon due to a strong covalent bond material, high power etching is performed in order to overcome endurance for etching, thus causing a phenomenon where a corner portion of the trench is more deeply etched as compared to the bottom due to high power etching. Accordingly, an electric field concentration phenomenon occurs at the corner portion of the trench causing breakage of an oxidation layer, thus deteriorating performance of the semiconductor device.

The information disclosed in this Background section is only for enhancement of understanding of the general background of the invention and should not be taken as an acknowledgement or any form of suggestion that this information forms the prior art already known to a person skilled in the art.

### SUMMARY OF INVENTION

The present invention has been made in an effort to prevent an electric field concentration phenomenon at a corner portion of a trench in a silicon carbide MOSFET to which a trench gate is applied.

Various aspects of the present invention provide for a method of manufacturing a semiconductor device, including: sequentially forming an n− type epitaxial layer, a p type epitaxial layer, and a first n+ region on a first surface of an n+ type silicon carbide substrate, and forming a trench through the first n+ region and the p type epitaxial layer and including a first portion having a linear profile and an oval second portion, wherein the forming of the trench includes forming a photosensitive layer pattern on the first n+ region, etching the first n+ region and the p type epitaxial layer by using the photosensitive layer pattern as a mask to form a first trench, forming a buffer layer by using amorphous carbon on the first n+ region and the first trench after the photosensitive layer pattern is removed, forming a buffer layer pattern by etching the buffer layer so as to expose a bottom of the first trench, etching the bottom of the first trench by using the buffer layer pattern as the mask to form a second trench, isotropically etching the second trench to form the second portion of the trench, and removing the buffer layer pattern.

A depth of the first trench may be ½ or less of the depth of the trench.

A width of the second trench may be smaller than the width of the first trench.

A total size of the first trench and the second trench may be ⅔ or less of the size of the trench.

The width of the first portion of the trench may be smaller than the width of the second portion of the trench.

The second portion of the trench may be positioned under the first portion of the trench.

The buffer layer pattern may be positioned on a sidewall of the first trench and the first n+ region.

The method of manufacturing a semiconductor device according to various aspects of the present invention may further include: after the forming of the trench, forming a gate insulating layer in the trench, forming a gate electrode on the gate insulating layer, forming an oxidation layer on the gate insulating layer and the gate electrode, patterning the first n+ region to form an n+ region, and forming a source electrode on the p type epitaxial layer, the n+ region, and the oxidation layer, and forming a drain electrode on a second surface of the n+ type silicon carbide substrate.

Various aspects of the present invention provide for a semiconductor device including: an n− type epitaxial layer, a p type epitaxial layer, and an n+ region sequentially disposed on a first surface of an n+ type silicon carbide substrate, a trench formed through the n+ region and the p type epitaxial layer, and including a first portion having a linear profile and an oval second portion, a gate insulating layer disposed in the trench, a gate electrode disposed on the gate insulating layer, an oxidation layer disposed on the gate electrode, a source electrode disposed on the p type epitaxial layer, the n+ region, and the oxidation layer, and a drain electrode positioned on a second surface of the n+ type silicon carbide substrate, wherein the second portion of the trench is disposed under the first portion of the trench, and a width of the second portion of the trench is larger than the width of the first portion of the trench.

According to various aspects of the present invention, it is possible to prevent a reduction in performance of a semiconductor device by including a first portion having a linear profile and an oval second portion having a width that is larger than the width of the first portion on a lower portion of the first portion in a trench to more deeply etch a corner portion of the trench as compared to a bottom, thus preventing a concentration phenomenon of an electric field at a corner portion.

Further, it is possible to easily form the trench including the first portion having the linear profile and the oval second portion by forming the first trench, forming a second trench by using a buffer layer pattern as a mask to form a second trench, and isotropically etching the second trench.

In addition, since the buffer layer pattern formed of amorphous carbon protects a sidewall of the first trench, it is possible to prevent an impurity from being formed at an interface between the buffer layer pattern and a sidewall of the first trench.

The methods and apparatuses of the present invention have other features and advantages which will be apparent from or are set forth in more detail in the accompanying drawings, which are incorporated herein, and the following Detailed Description, which together serve to explain certain principles of the present invention.

### BRIEF DESCRIPTION OF THE DRAWINGS

FIG. 1 is a cross-sectional view of an exemplary semiconductor device according to the present invention.

FIGS. 2 to 9 are views sequentially showing an exemplary method of manufacturing the semiconductor device according to the present invention.

### DETAILED DESCRIPTION

Reference will now be made in detail to various embodiments of the present invention(s), examples of which are illustrated in the accompanying drawings and described below. While the invention(s) will be described in conjunction with exemplary embodiments, it will be understood that present description is not intended to limit the invention(s) to those exemplary embodiments. On the contrary, the invention(s) is/are intended to cover not only the exemplary embodiments, but also various alternatives, modifications, equivalents and other embodiments, which may be included within the spirit and scope of the invention as defined by the appended claims.

In the drawings, the thickness of layers, films, panels, regions, etc., are exaggerated for clarity. Further, it will be understood that when a layer is referred to as being “on” another layer or substrate, it can be directly on the other layer or substrate, or intervening them may also be present. Like reference numerals designate like elements throughout the specification.

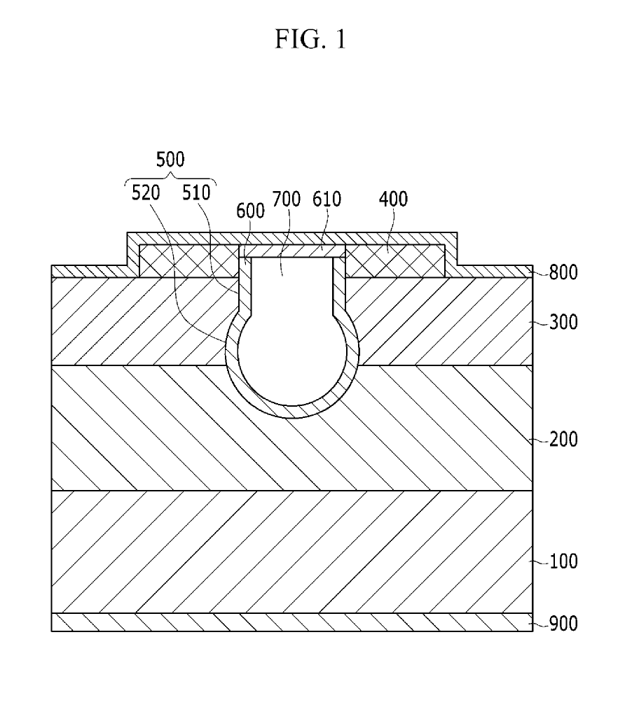

FIG. 1 is a cross-sectional view of a semiconductor device according to various embodiments of the present invention.

Referring to FIG. 1, in the semiconductor device according to various embodiments, an n− type epitaxial layer 200, a p type epitaxial layer 300, and an n+ region 400 are sequentially disposed on a first surface of an n+ type silicon carbide substrate 100.

A trench 500 is disposed on the n− type epitaxial layer 200, the p type epitaxial layer 300, and the n+ region 400. The trench 500 is formed through the n+ region 400 and the p type epitaxial layer 300. The trench 500 includes a first portion 510 having a linear profile and an oval second portion 520. Herein, the second portion 520 is positioned on a lower portion of the first portion 510, and a width of the second portion 520 is larger than that of the first portion 510.

A gate insulating layer 600 is disposed in the trench 500, a gate electrode 700 is disposed on the gate insulating layer 600, and an oxidation layer 610 is disposed on the gate insulating layer 600 and the gate electrode 700. The gate electrode 700 fills the trench 500.

A source electrode 800 is formed on the p type epitaxial layer 300, the n+ region 400, and the oxidation layer 610.

A drain electrode 900 is formed on a second surface of the n+ type silicon carbide substrate 100.

As described above, it is possible to prevent a reduction in performance of the semiconductor device by including the first portion 510 having the linear profile and the oval second portion 520 having the width that is larger than the width of the first portion 510 on a lower portion of the first portion 510 in the trench 500 to more deeply etch a corner portion of the trench 500 as compared to a bottom, thus preventing a concentration phenomenon of an electric field at the corner portion.

Then, referring to FIGS. 2 to 3 and FIG. 1, a method of manufacturing the semiconductor device according to various embodiments of the present invention will be described in detail.

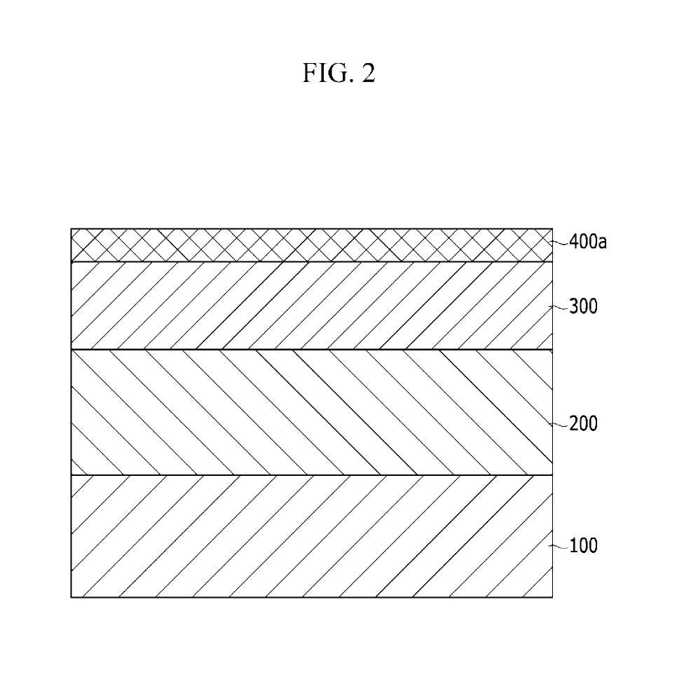

FIGS. 2 to 9 are views sequentially showing a method of manufacturing the semiconductor device according to various embodiments of the present invention.

As shown in FIG. 2, the n+ type silicon carbide substrate 100 is prepared, an epitaxial growth is performed on a first surface of the n+ type silicon carbide substrate 100 to form the n− type epitaxial layer 200, the epitaxial growth is performed on the n− type epitaxial layer 200 to form the p type epitaxial layer 300, and the epitaxial growth is performed on the p type epitaxial layer 300 to form a first n+ region 400a.

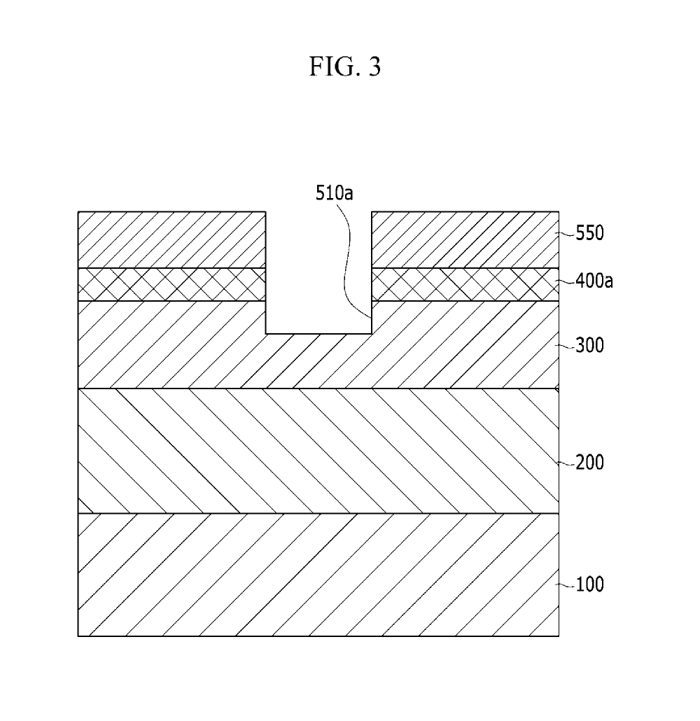

As shown in FIG. 3, after a photosensitive layer pattern 550 is formed on the first n+ region 400a, the first n+ region 400a and the p type epitaxial layer 300 are etched by using the photosensitive layer pattern 550 as the mask to form a first trench 510a. A depth of the first trench 510a may be ½ or less of the depth of the trench 500. Herein, the sidewall of the first trench 510a is the first portion 510 of the trench 500.

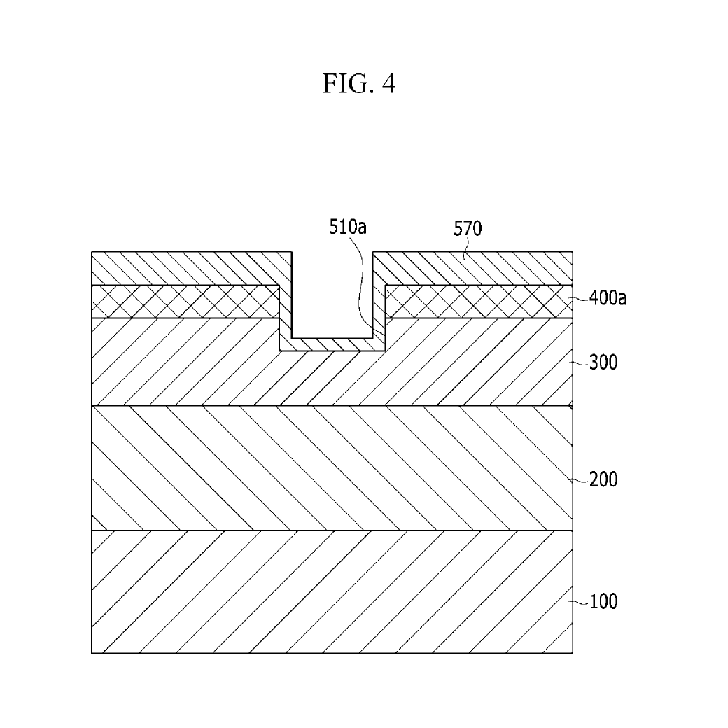

As shown in FIG. 4, after the photosensitive layer pattern 550 is removed, a buffer layer 570 is formed on the first n+ region 400a and the first trench 510a. The buffer layer 570 is formed of amorphous carbon. It is possible to prevent an impurity from being formed at an interface between silicon carbide and the buffer layer 570 by bringing silicon carbide and amorphous carbon into contact with each other.

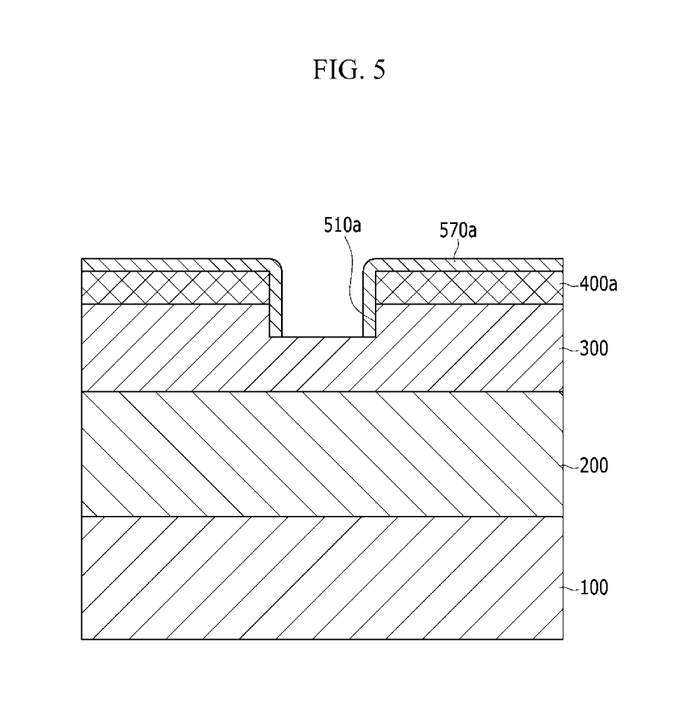

As shown in FIG. 5, the buffer layer 570 is etched to expose the bottom of the first trench 510a, thus forming a buffer layer pattern 570a. The buffer layer pattern 570a is positioned on the sidewall of the first trench 510a and the first n+ region 400a.

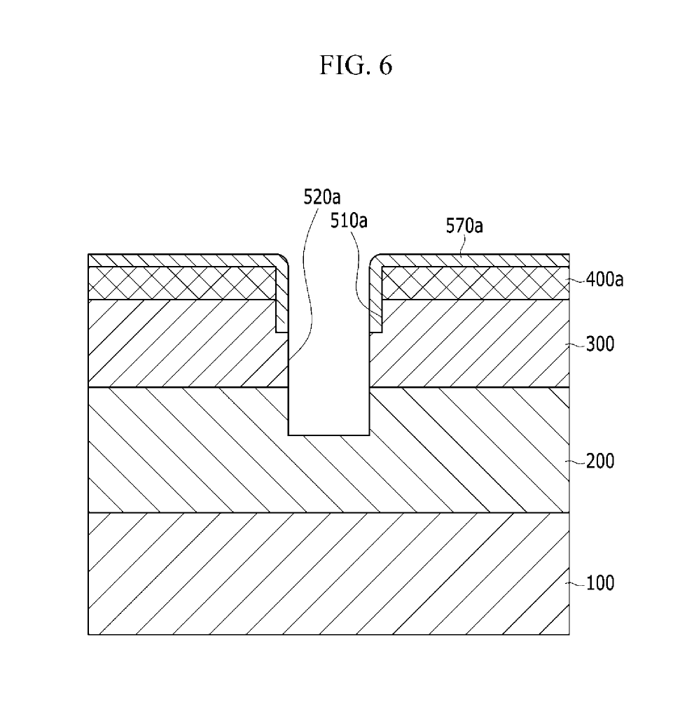

As shown in FIG. 6, the exposed bottom of the first trench 510a is etched by using the buffer layer pattern 570a as the mask to form a second trench 520a. Herein, the width of the second trench 520a is smaller than that of the first trench 510a. Further, the total size of the first trench 510a and the second trench 520a may be ⅔ or less of the size of the trench 500.

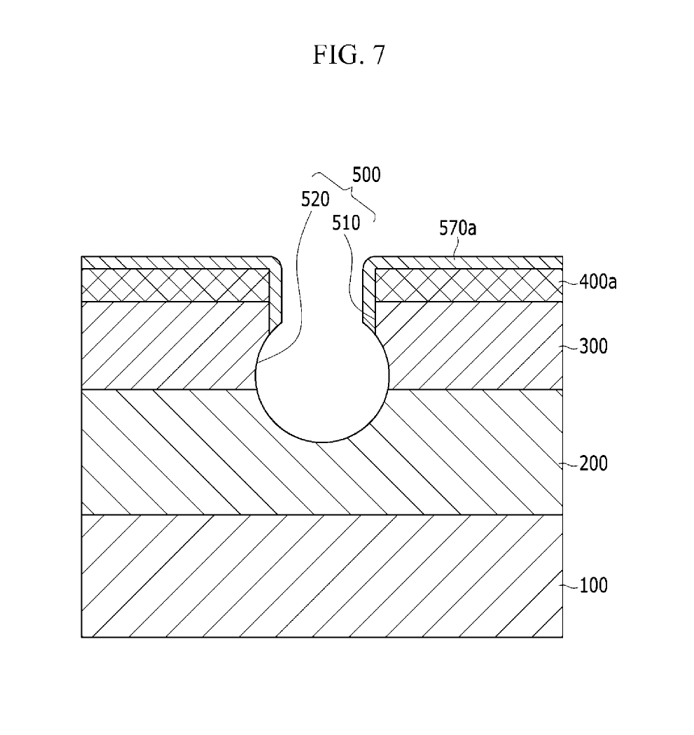

As shown in FIG. 7, the second trench 520a is isotropically etched to form the second portion 520 of the oval trench 500, thus completing the trench 500. The sidewall of the first trench 510a is protected by the buffer layer pattern 570a not to allow the first trench to be etched, but only the second trench 520a is etched, such that the trench 500 includes the first portion 510 having the linear profile and the oval second portion 520 having the width that is larger than that of the first portion 510 on the lower portion of the first portion 510. Further, since the buffer layer pattern 570a is formed of amorphous carbon, the impurity is not formed at the interface between the sidewall of the first trench 510a and the buffer layer pattern 570a.

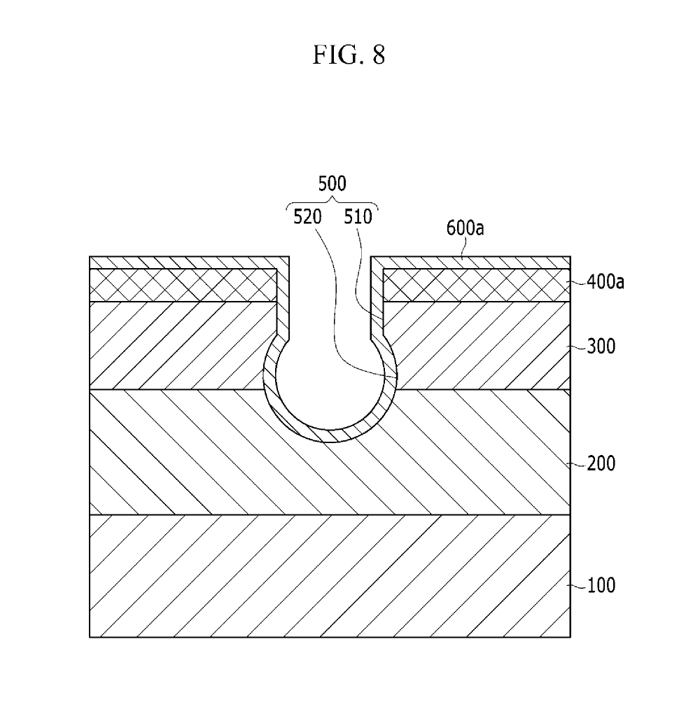

As shown in FIG. 8, after the buffer layer pattern 570a is removed, the insulating layer 600a is formed on the trench 500 and the first n+ region 400a.

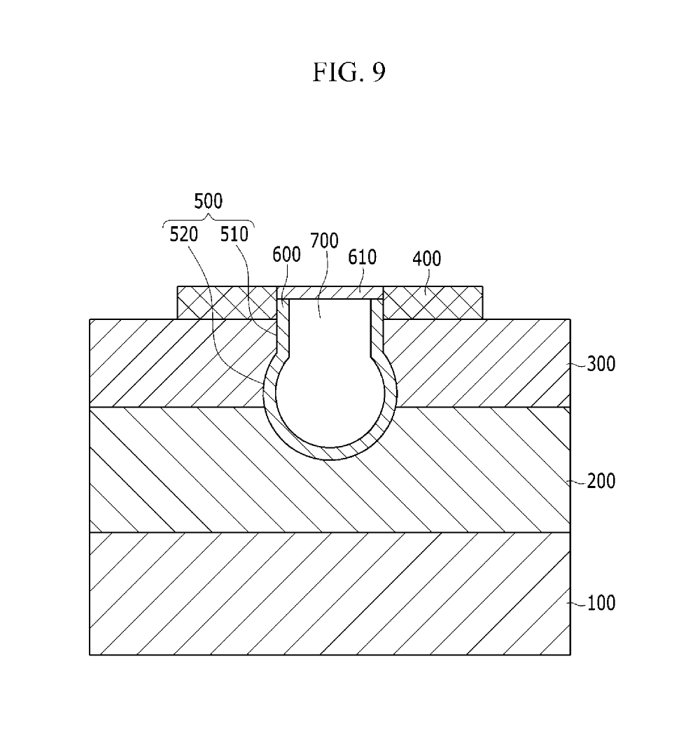

As shown in FIG. 9, the insulating layer 600a is etched to form the gate insulating layer 600 in the trench 500, a gate electrode 700 is formed on the gate insulating layer 600, the oxidation layer 610 is formed on the gate insulating layer 600 and the gate electrode 700, and the first n+ region 400a is patterned to form the n+ region 400.

In various embodiments, the n+ region 400 is formed by performing patterning after an epitaxial growth is performed, but may be formed by injecting n+ ions into a portion of a surface of the p type epitaxial layer 300.

As shown in FIG. 1, a source electrode 800 is formed on the p type epitaxial layer 300, the n+ region 400, and the oxidation layer 610, and a drain electrode 900 is formed on a second surface of the n+ type silicon carbide substrate 100.

As described above, after the first trench 510a is formed, the second trench 520a may be formed by using the buffer layer pattern 570a as the mask, and the second trench 520a may be isotropically etched to easily form the trench 500 including the first portion 510 having the linear profile and the oval second portion 520.

Further, since the buffer layer pattern 570a formed of amorphous carbon protects the sidewall of the first trench 510a, it is possible to prevent the impurity from being formed at the interface between the buffer layer pattern 570a and the sidewall of the first trench 510a.

For convenience in explanation and accurate definition in the appended claims, the terms lower, and etc. are used to describe features of the exemplary embodiments with reference to the positions of such features as displayed in the figures.

The foregoing descriptions of specific exemplary embodiments of the present invention have been presented for purposes of illustration and description. They are not intended to be exhaustive or to limit the invention to the precise forms disclosed, and obviously many modifications and variations are possible in light of the above teachings. Various embodiments were chosen and described in order to explain certain principles of the invention and their practical application, to thereby enable others skilled in the art to make and utilize various exemplary embodiments of the present invention, as well as various alternatives and modifications thereof. It is intended that the scope of the invention be defined by the Claims appended hereto and their equivalents.

1. A method of manufacturing a semiconductor device, comprising:
sequentially forming an n− type epitaxial layer, a p type epitaxial layer, and a first n+ region on a first surface of an n+ type silicon carbide substrate; and
forming a trench through the first n+ region and the p type epitaxial layer and including a first portion having a linear profile and an oval second portion;
wherein the forming of the trench includes:
forming a photosensitive layer pattern on the first n+ region;
etching the first n+ region and the p type epitaxial layer by using the photosensitive layer pattern as a mask to form a first trench;
forming a buffer layer by using amorphous carbon on the first n+ region and the first trench after the photosensitive layer pattern is removed;
forming a buffer layer pattern by etching the buffer layer so as to expose a bottom of the first trench;
etching the bottom of the first trench by using the buffer layer pattern as the mask to form a second trench;
isotropically etching the second trench to form the second portion of the trench; and
removing the buffer layer pattern,
wherein the buffer layer pattern is positioned on a sidewall of the first trench and the first n+ region.

2. The method of manufacturing a semiconductor device of claim 1, wherein a depth of the first trench is ½ or less of the depth of the trench.

3. The method of manufacturing a semiconductor device of claim 2, wherein a width of the second trench is smaller than a width of the first trench.

4. The method of manufacturing a semiconductor device of claim 3, wherein a total size of the first trench and the second trench is ⅔ or less of the size of the trench.

5. The method of manufacturing a semiconductor device of claim 4, wherein the width of the first portion of the trench is smaller than the width of the second portion of the trench.

6. The method of manufacturing a semiconductor device of claim 5, wherein the second portion of the trench is positioned under the first portion of the trench.

7. (canceled)

8. The method of manufacturing a semiconductor device of claim 1, further comprising after the forming of the trench:
forming a gate insulating layer in the trench;
forming a gate electrode on the gate insulating layer;
forming an oxidation layer on the gate insulating layer and the gate electrode;
patterning the first n+ region to form a n+ region; and
forming a source electrode on the p type epitaxial layer, the n+ region, and the oxidation layer, and forming a drain electrode on a second surface of the n+ type silicon carbide substrate.

9. (canceled)
